(19) United States
(12) Patent Application Publication
(10) Pub. No.: US 2007/0133261 A1
(43) Pub. Date: Jun. 14, 2007

(54) Semiconductor storage device

(75) Inventors: Tomoya Tsuruta, Kawasaki (JP); Hiroshi Shimizu, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/698,880

(22) Filed: Jan. 29, 2007

Related U.S. Application Data
(63) Continuation of application No. PCT/JP04/11487, filed on Aug. 10, 2004.

(51) Int. Cl. G11C 11/00

(52) U.S. Cl. 365/154

(57) ABSTRACT

A semiconductor storage device such as a memory cell, a latch, etc. provides a memory cell or other such memory device that has a high immunity to soft errors. The device includes an inverter composed of a paired N-type transistors and a paired P-type transistor, and each of transistor is disposed on a separate well. The device also includes four such transistor pairs coupled to each other, and a gate-to-node connection device for connecting to a gate of each P-type transistor and each N-type transistor a connection node for connection of the P-type transistor to the N-type transistor in each pair of transistors in such a direction so as to prevent a potential inversion of a node caused by a soft error from propagating to another node.

### CROSS REFERENCE TO RELATED APPLICATION

This application is a continuation of PCT application PCT/JP2004/011487, which was filed on Aug. 10, 2004.

### BACKGROUND OF THE INVENTION

1. Field of the Invention

The present invention relates to the structure of a semiconductor storage device, and more specifically to a semiconductor storage device having a high immunity to the potential inversion of a semiconductor node caused by an occurrence of electric charge that is due to collisions between energy particles existing in the surrounding space of a semiconductor, that is, a soft error.

2. Description of the Related Art

In a field effect transistor (MOSFET), when an α-line particle or other such particle collides with a node of a transistor, an electron and a hole are generated. When the amount of generated charge exceeds the critical charge of the node, a potential inversion occurs. Such a malfunction does not occur due to a hardware defect, but is referred to as a soft error.

In order to prevent such a soft error, adding capacitance to a node in which there is a possibility of a potential inversion is effective. However, it is hard to reserve an area to which a large capacitance can be added, and it is disadvantageous in cost to add capacitance via the addition of a production process for a semiconductor cell. Measures to correct errors such as an ECC have considerable penalties for processing speed, and have the problem that the ECC is less efficient in area in a latch when small data unit is processed than is RAM when relativelya large dataunitisprocessed. When a majority rule is adopted using a triple structure in the latch, a problem arises in which an area of three times or more is required even though the process is relatively simple and appropriate for small-scale data processing.

With the scaling down of recent wafer technology, occurrences of soft errors have reached an unignorable level, even in normal latches other than RAM. There exist the conventional techniques described in the following documents as countermeasures against the above-mentioned soft errors.
Patent Document 1: Japanese Published Patent Application No. H7-7089, “Storage Cell”

This document discloses the technique of improving the ratio of the amount of collected charge to the capacitance of a node when charged particles are input by dividing a first type (N-type) transistor constituting a latch into two portions, and separately disposing them using a second type (P-type) well, thereby reducing the occurrence rate in software. However, it is necessary to also take measures not only for the N-type (N channel) transistors but also for the P-type (P channel) transistors to completely suppress soft errors. Furthermore, the technique cannot solve the problem that a storage state can be inverted when a large charge caused by a neutron line occurs, even though the ratio of the node capacitance to the amount of collected charge is relatively low.

The objective of the present invention is to provide a semiconductor storage device having a high immunity to soft errors, for example, a CMOS static RAM, a latch, etc.

### SUMMARY OF THE INVENTION

The semiconductor storage device according to the present invention includes an inverter composed of a paired N-type transistors and a paired P-type transistor, and each of transistors is disposed on a separate well.

The semiconductor storage device according to the present invention includes four such transistor pairs consisting of an N-type transistor and a P-type transistor coupled to each other, and a gate-to-node connection device for connecting a connection node to a gate of each transistor so that the P-type transistor and the N-type transistor in each transistor pair are connected in such a direction so as to prevent a potential inversion of a node caused by a soft error from propagating to another node. Then, the four pairs of transistors are paired into two sets, and each set of paired transistors is disposed on a separate well.

As described above, according to the present invention, by disposing on a separate well the P-type transistor and the N-type transistor in a pair of paired transistor sets in which paired P-type and N-type transistors or N-type and P-type transistors constituting an inverter are connected, immunity to soft errors can be enhanced. In addition, by connecting the connection nodes of for pairs of transistors to the gate of each transistor in such a direction so as to prevent a potential inversion in a node from propagating to another node, errors are prevented from propagating to an adjacent node even when a large charge occurs in one node.

### BRIEF DESCRIPTION OF THE DRAWINGS

FIG. 1 shows a circuit of the configuration according to the first embodiment of the semiconductor storage device of the present invention;

FIG. 2 is an explanatory view of the layout corresponding to the circuit shown in FIG. 1;

FIG. 3 shows a circuit of the configuration according to the second embodiment of the semiconductor storage device;

FIG. 4 is an explanatory view of the layout corresponding to the circuit shown in FIG. 3;

FIG. 5 shows an example of data storage status according to the second embodiment;

FIG. 6 is an explanatory view of example (1) of a state transition when a soft error occurs in the second embodiment;

FIG. 7 is an explanatory view of example (2) of a state transition when a soft error occurs in the second embodiment;

FIG. 8 shows a circuit of the configuration according to the third embodiment of the semiconductor storage device;

FIG. 9 is an explanatory view showing an example of the state transition when data 0 is written according to the third embodiment; and

FIG. 10 shows a circuit of the configuration according to the fourth embodiment of the semiconductor storage device.

### DESCRIPTION OF THE PREFERRED EMBODIMENTS

First, the principle of the present invention is explained below. In the present invention, a layout can, for example, be designed such that P-type and N-type transistors constituting an inverter in a storage cell can be paired and each of the transistor pairs is disposed on a separate well.

The semiconductor storage device according to the present invention includes four pairs of transistors that consist of one N-type and one P-type transistor coupled to each other, gate-to-node connection wires for connecting a connection node to a gate of each transistor so that the P-type transistor and the N-type transistor in each transistor pair can be connected in such a direction so as to prevent a potential inversion of a node caused by a soft error from propagating to another node. Then, the four pairs of transistors are paired into two sets, and each and each set of paired transistors is disposed on a separate well.

The four pairs of transistors can be designed to form a total of four stages of loop structure in the back and forth directions, that is, paired transistor sets can be formed by one pair with another pair two stages backward. In this case, a gate-to-node connection wire can connect the above-mentioned connection node to the gate of the P-type transistor in the pair of transistors at the subsequent stage and the gate of the N-type transistor in the pair of transistors at the preceding stage. In the present invention, a transistor can also be connected to receive an input signal from or to output an output signal to the connection nodes of the P-type transistor and the N-type transistor in each of the four pairs of transistors.

Furthermore, in the present invention, input data can be supplied to two of the connection nodes in a pair of transistors in a set of paired transistors, and output data can be output from one of the connection nodes in a pair of transistors in another set of paired transistors.

In this case, a transmission gate for reception of input data can be provided for each of the two connection nodes that receive input data, and an inverter can be provided between a connection gate for the output of output data and an external unit.

Alternately, a clocked inverter for reception of input data can be provided for each of the two connection nodes to which input data is supplied, with the inverter connected to the connection node for output of output data, and a transistor whose gate receives a clock signal and a transistor whose gate receives an inverted signal of a clock can be connected to each of the transistors in the other set of paired transistors. In this case, the value of the clock signal operated by the clocked inverter that receives input data can be the inverse of the value of the clock signal according to which the two transistors connected to the other set of paired transistors are turned on.

The modes for embodying the present invention are explained below in more detail by referring to the attached drawings.

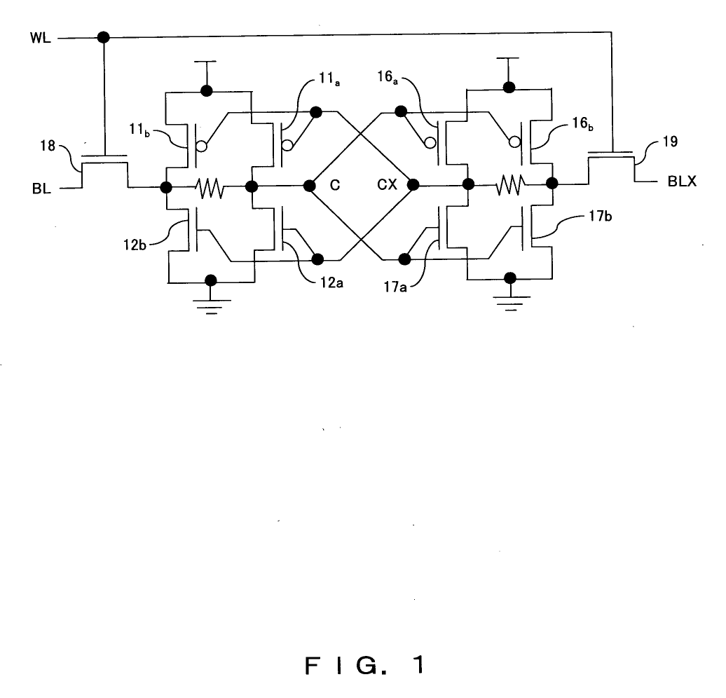

FIG. 1 shows a circuit of the configuration according to the first embodiment of the semiconductor storage device of the present invention; for example, a static RAM cell, or a latch. FIG. 1 shows a circuit of the semiconductor storage device having a high immunity to soft errors by two paired inverters constituted by an N-type and P-type transistor pair forming a RAM cell or a latch.

In FIG. 1, the transistors 11a and 12a, and 11b and 12b whose gates are connected to nodes CX are paired inverters. Therefore, the transistors 11a and 11b are paired P-type transistors, and the transistors 12a and 12b are paired N-type transistors.

Similarly, the P-type transistors 16a and 16b and the N-type transistors 17a and 17b whose gates are connected to nodes C are respectively the P-type transistors and the N-type transistors constituting paired inverters. Nodes C and CX indicate an H level in the state in which the semiconductor storage device stores 1 and 0 respectively, and refer to, for example, a positive node and a negative node.

The connection points (nodes) of transistors 11a and 12a, and 11b and 12b are connected to the bit lines BL through transistor 18. Similarly, the connection point of transistors 16a and 17a, and 16b and 17b are connected to the bit line BLX through transistor 19. A word line WL is connected to the gates of transistors 18 and 19.

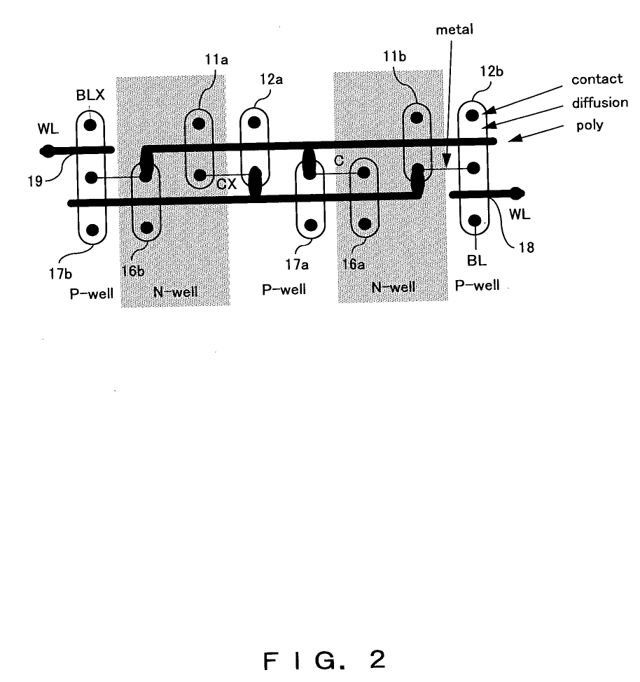

FIG. 2 is an explanatory view of the layout of the paired transistors in the circuit shown in FIG. 1. In FIG. 2, paired transistors 11a and 11b, 12a and 12b, 16a and 16b, and 17a and 17b shown in FIG. 1 are separately disposed with distances on different wells.

That is, in FIG. 2, the N-type transistors 12a and 17a are disposed on the central P-well. On the N-well to the right of them, the P-type transistors 16a and 11b are disposed. On the N-well to the left, the P-type transistors 11a and 16b are disposed. On the rightmost P-well, the N-type transistor 12b is disposed. On the leftmost P-well, the N-type transistor 17b is disposed.

In FIG. 2, the horizontal bold line shows plural poly-silicon connections to node C or CX shown in FIG. 1, and the short and bold lines on the right and left show plural poly-silicon connections to the word line WL. Below the short and bold lines, the transistors 18 and 19 connected to the bit line BL or BLX shown in FIG. 1 are constituted.

As described above, in the first embodiment, the P-type and N-type transistors of two inverters constituting, for example, a latch, are paired, and each of the paired transistors is disposed on the well next to another type of well or separately with a distance, and a corresponding node is connected to each node of paired transistors. The electronic charge from charged particles causing a local soft error occurs, and there is a low probability that charge will occur in the areas of both simultaneously paired transistors. Although charge occurs on one well, it is rare that the electric charge will pass over the barrier of the well. Thus, the amount of critical the electric charge of a node can be increased, and the ratio of the electric charge collection area to the amount of critical charge in a node when charged particles enter can be decreased, thereby enhancing the immunity to soft errors.

Furthermore, in the layout shown in FIG. 2, when, for example, paired transistors are disposed on separate wells and two transistors are placed on the same well, a layout including a transistor whose gate is connected to a positive node C and a transistor whose gate is connected a negative node CX is used. The positive node C and the negative node CX corresponding to the P-type transistor or the N-type transistor on the same well have a complementary relationship with each other in maintaining a given status, are never simultaneously accumulation nodes, and do not simultaneously cause an error when charged particles enter.

Also in FIG. 2, it is considered that the electric charge occurring when charged particles enter rarely occurs over a plurality of wells. Therefore, the diffusion that causes soft errors occurs only in one of the two sets of copy transistors corresponding to the storage nodes C and CX of cells. As a result, the ratio of the collected electric charge to the capacitance of a node can be improved as described above, thereby reducing the soft error rate.

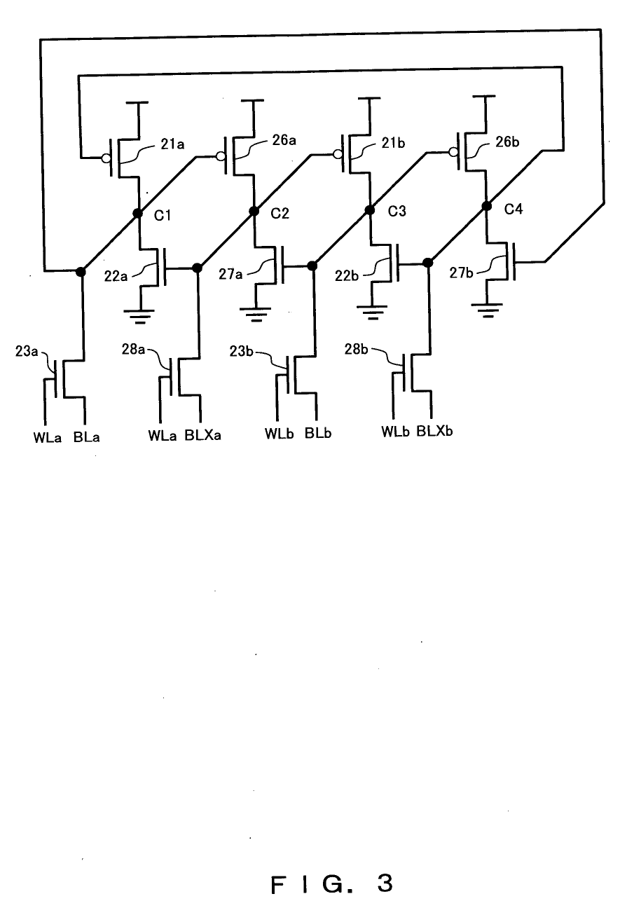

FIG. 3 shows a circuit of the configuration according to the second embodiment of the semiconductor storage device. In FIG. 3, the semiconductor storage device is essentially constituted by four pairs of P-type and N-type MOS transistors. In FIG. 3, a pair of transistors including a P-type transistor 21a and an N-type transistor 22a and a pair transistors including a P-type transistor 21b and an N-type transistor 22b are corresponding paired transistor sets. Similarly, the transistor pair including transistors 26a and 27a, the transistor pair including transistors 26b and 27b, and the transistor pair including transistors 26b and 27b are paired transistor sets.

Then, for example, node C1 for connection of the first pair of transistors 21a and 22a is connected to the gate of the P-type transistor 26a and the gate of the N-type transistor 27b, and to the bit line BLa through transistor 23a. The word line WLa is connected to the gate of transistor 23a.

Similarly, the connection node C2 for the second pair of the transistors, that is, the P-type transistor 26a and the N-type transistor 27a, is connected to the gate of the P-type transistor 21b and the gate of the N-type transistor 22a, and is connected to the bit line BLXa through transistor 28a. The gate of transistor 28a is connected to the word line WLa. Similar connections are made for node C3 for the third transistor pair and node C4 for the fourth transistor pair. The connection wires between nodes C1 through C4 and the gate of each transistor correspond to the gate-to-node connection device according to claim 2 of the present invention.

In the second embodiment, the first and third transistor pairs form a paired set, and the second and fourth transistor pairs form another paired set. The node for connection between the P-type transistor and the N-type transistor in each transistor pair is connected to the gate of the P-type transistor at the subsequent stage and the gate of the N-type transistor at the preceding stage. With this configuration, even if electric charge exceeding the amount of critical electric charge occurs in one node when charged particles enter, the error state does not easily propagate to the subsequent or preceding node, and the immunity to soft errors can be further enhanced. The effect is described in further detail later.

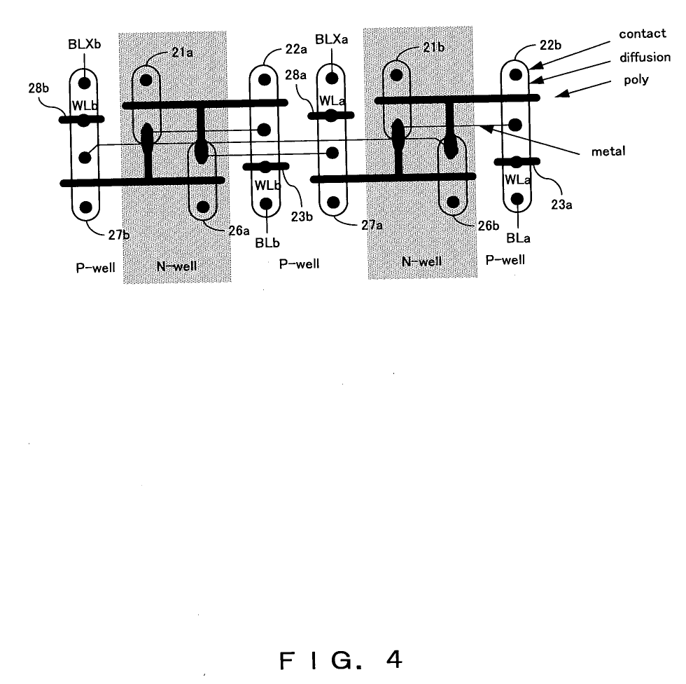

FIG. 4 shows an example of a layout of the circuit shown in FIG. 3. In FIG. 4, as in FIG. 2, two N-wells are disposed on both sides of the central P-wells, and two outer P-wells are further disposed. The N-type transistors 22a and 27a are disposed at the central P-wells, the P-type transistors 21b and 26b are disposed on the right N-well, and the P-type transistors 21a and 26a are disposed on the left N-wells. The N-type transistor 22b is disposed on the rightmost P-well, and the N-type transistor 27b is disposed on the leftmost P-well. This disposition example is a practical example of an appropriate disposition in which wires can be easily set and the setting areas are reduced.

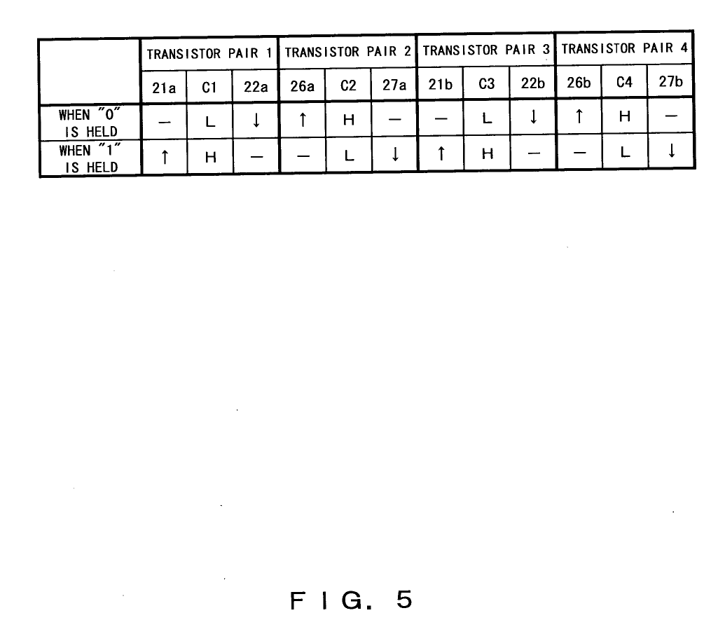

FIG. 5 shows an example of a data storage status, that is, a data holding status, according to the second embodiment of the semiconductor storage device shown in FIG. 3. In FIG. 5, as described above, transistor pairs 1 and 3, and transistor pairs 2 and 4 are paired transistor sets. In the connection nodes between the P-type transistors and the N-type transistors nodes C1 and C3, and C2 and C4 have the same respective values as the paired nodes.

In FIG. 5, when data 0 is held in the storage device (for example, memory), nodes C1 and C3 indicate L, and nodes C2 and C4 indicate H. The states of each transistor constituting a transistor pair are expressed by “−” for indicating the off state, “↓” for dropping the node to L when it is turned on, or “↑” for raising the potential of the node to H when it is turned on. The voltage states of each node are expressed by “H” for indicating a high voltage state, “M” for indicating an intermediate potential state, or “L” for indicating a low voltage state.

When data 1 is held by the function of memory, nodes C1 and C3 show H, nodes C2 and C4 show L, and the state of each pair of transistors is expressed by either a minus sign, a down arrow, or an up arrow.

To write data 0 in FIG. 5, the word lines WLa and WLb should simultaneously indicate the H level, and the bit lines BLa and BLb should indicate the L level in FIG. 3. To write data 1, the word lines WLa and WLb should simultaneously indicate the H level, and the bit lines BLXa and BLXb should be set as the L level. When data is read, using each of the sets WLa, BLa, BLXa and WLb, BLb, BLXb independently, the function as a storage device having two read ports can be realized. By providing the same signal as in writing data without differentiating the two sets, the function of a normal 1-port RAM cell or a latch can be realized.

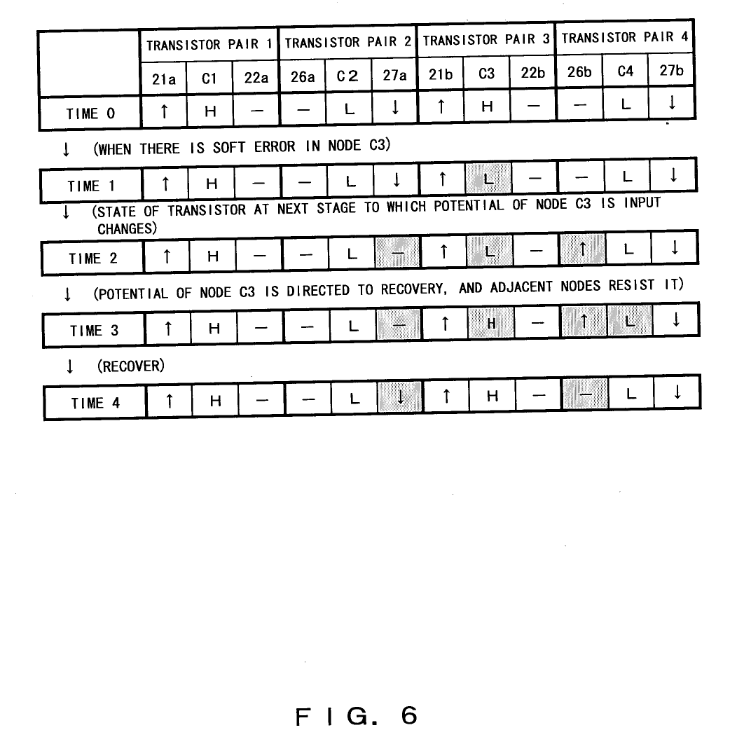

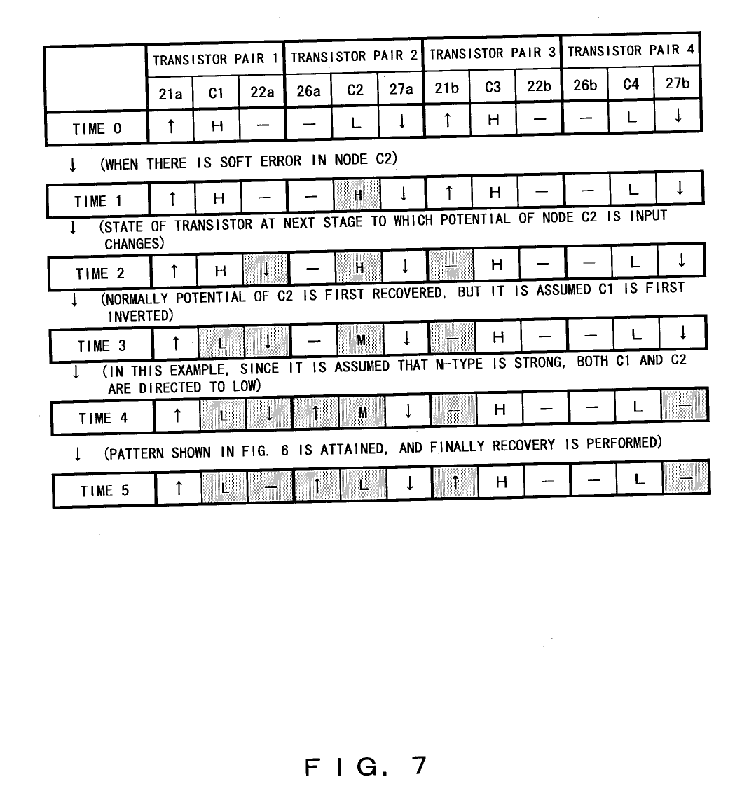

FIGS. 6 and 7 are explanatory views of an example of a state transition to the recovery of a state when a soft error occurs in the circuit shown in FIG. 3, that is, when the potential of one node is inverted. In the present mode for embodying the present invention, the N-type transistor is stronger in the transistor pair consisting of a P-type transistor and an N-type transistor, that is, the size and the current are higher, the operation as a pair of transistors is dominant, and the state can be more easily recovered than when the inversion occurs from L to H.

FIG. 6 shows an example of the state transition that exists for the inversion direction of potential that can be more easily recovered, that is, when the inversion of potential from H to L has occurred in node C3. In FIG. 3, at time 0, control is in the state in which “1” shown in FIG. 5 is held, and it is assumed that the potential of node C3 has inverted to L at time 1 due to a soft error.

Node C3 is connected to the gate of the P-type transistor 26b and the gate of the N-type transistor 27a in FIG. 3, and the transistor 26b is in the ON state at time 2 and raises the potential of node C4. The transistor 27a is in the OFF state.

Then, the potential of node C3 is directed to recovery at time 3. However, since both transistors 26a and 27a are in the OFF state for a long time, node C2 shows almost no changes in potential, and transistor 26b is turned on in the transistor pair 4, thereby raising the potential of node C4 to H while the N-type transistor 27b is also in the ON state, thereby reducing the potential of node C4 to L. As a result, the change in potential of node C4 is also moderate. Therefore, the erroneous node C3 is first recovered, and the potential of node C3 is recovered toH at time 4 while the N-type transistor 27a is turned on and drops node C2 to L. The P-type transistor 26B is turned off, and the potential of node C4 is maintained at L.

FIG. 7 shows an example of a state transition from L to H that implies a more difficult recovery in the node potential inversion direction than in the case shown in FIG. 6. In FIG. 7, it is assumed that the potential of node C3 shown in FIG. 3 has been inverted by a soft error from L at time 0 to H at time 1.

At time 2, the gate of the P-type transistor 21b is provided with the potential of node C2 turned off and the N-type transistor 22a is changed from the off state to the on state, thereby dropping the potential of node C1 to L. Normally, node C2, whose potential has been inverted due to a soft error, is recovered first. However, since the trend to recovery is lower than the case shown in FIG. 6, it is assumed that the potential of node C1 is inverted before the recovery of the potential of node C2. At time 3, the potential of node C2 is M between H and L, and the potential of node C1 is inverted to L. However, the P-type transistor 21a and the N-type transistor 22a forming the transistor pair 1 are in the ON state, and the potential change of node C1 becomes moderate.

It is assumed that the N-type transistor is stronger, the potential of nodes C1 and C2 is directed to L by the operation of the N-type transistor at time 4, and a pattern corresponding to that at time 2 shown in FIG. 6 is attained at time 5. That is, the states at time 2 shown in FIG. 6 and at time 5 shown in FIG. 7 are caused to be the same by exchanging the states of the transistor pairs 3 and 4 with the states of the transistor pairs 1 and 2. In FIG. 3, since the transistor pairs 1 and 3 and the transistor pairs 2 and 4 correspond to paired transistor sets, the entire operation remains the same even if the state data are exchanged between the transistor pairs 1 and 3 and the transistor pairs 2 and 4. Therefore, the subsequent state transition appears from time 2 to time 4 shown in FIG. 6, and finally the state transition at time 0 shown in FIG. 7 is attained.

That is, according to the second embodiment, even if a large electric charge occurs due to, for example, a neutron line in a node and the potential is inverted, the possibility that the influence will reach an adjacent node is very small.

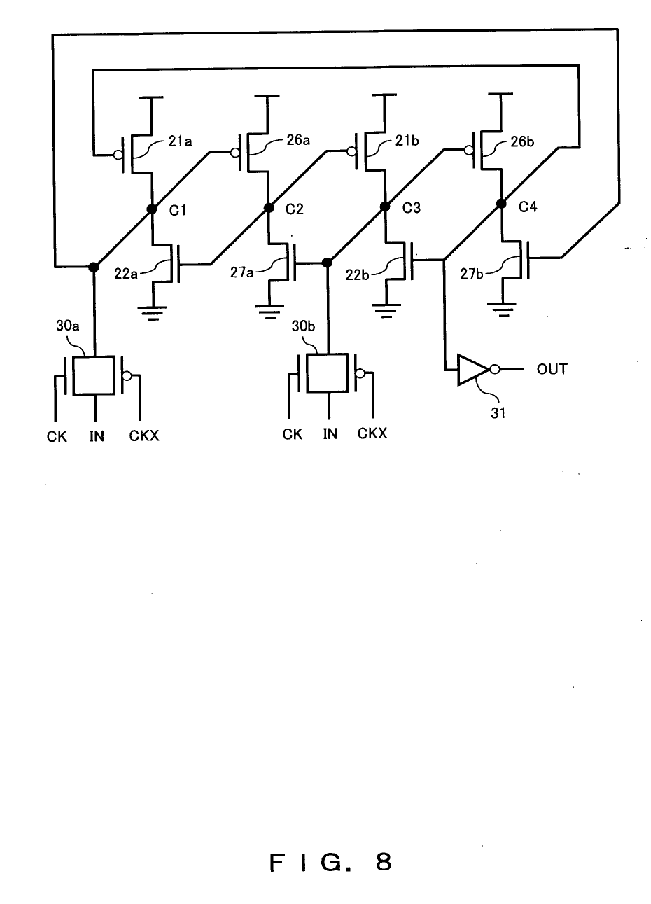

FIG. 8 shows the circuit according to the third embodiment of the semiconductor storage device. In FIG. 8, the storage device, for example, the four transistor pairs as basic components of a latch, has the same configuration as the device shown in FIG. 3, but is different in transmission gates 30a and 30b for supplying input to nodes C1 and C3, and in inverter 31 for retrieving output from node C4. In this circuit, as in the case shown in FIG. 3, the state of holding “0” as shown in FIG. 5 can be attained by, for example, supplying data 0 to nodes C1 and C3, that is, driving nodes C1 and C3 to L.

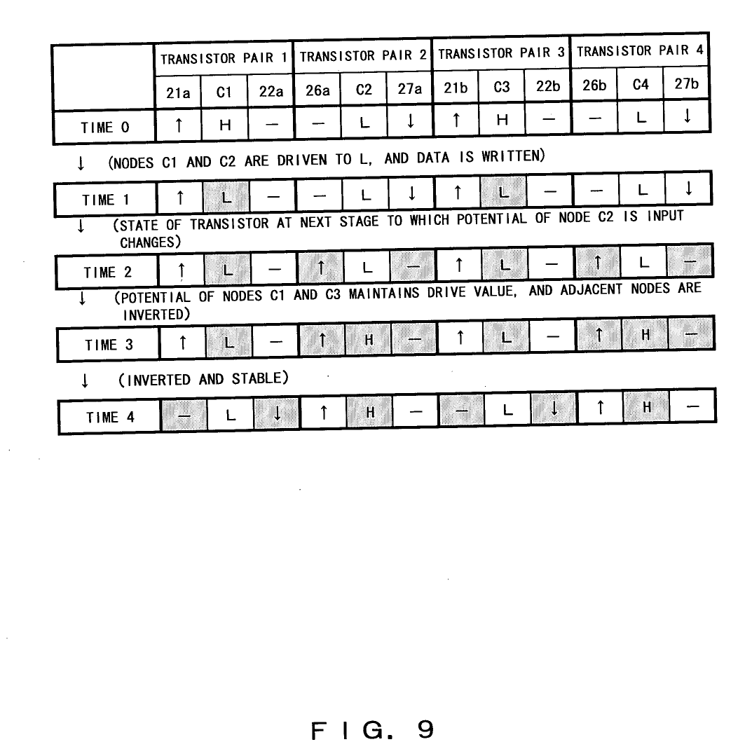

FIG. 9 show an example of the state transition when data 0 is written. In FIG. 9, the state of holding “1” shown in FIG. 5 is maintained at time 0. In this state, “0” is written by driving nodes C1 and C3 to L at time 1.

That is, at time 2, the state of the transistor to which the nodes are connected is changed by the change of the potential of nodes C1 and C3. That is, in the transistor pair 2, the P-type transistor 26a is turned on to raise the potential of node C2 to H while the N-type transistor 27a is turned off. The transistor 26b in the transistor pair 4 is turned on to raise the potential of node C4 while the N-type transistor 27b is turned off.

At time 3, the potential of nodes C1 and C3 keeps the value obtained when they are driven, and the nodes on both ends, that is, the potential of nodes C2 and C4 is inverted from L to H. Thus, at time 4, the P-type transistor 21a of the transistor pair 1 is turned off, and the N-type transistor 22a is turned onto raise the potential of node C1 to L. The P-type transistor 21b of the transistor pair 3 is turned off, and the N-type transistor 22b is turned on to drop the potential of node C3 to L. Thus, the operation becomes stable, and the state transition to the state when “0” is held shown in FIG. 5 terminates.

That is, in the second and third embodiments, data can be completely written by providing two input values (the same values) for two nodes when data is written.

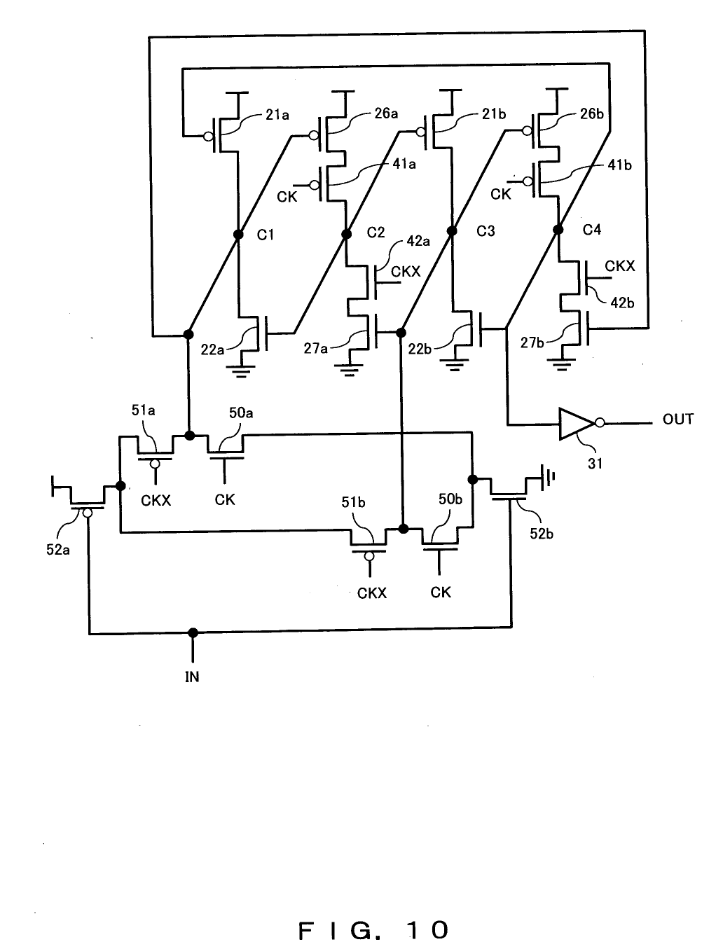

FIG. 10 shows a circuit according to the fourth embodiment of the semiconductor storage device. This embodiment is realized by replacing the two transmission gates for writing data in the third embodiment shown in FIG. 8 with clocked inverters, and connecting P-type transistors for supplying a clock signal CK to the gates of two of the four transistor pairs and N-type transistors for supplying an inverted signal CKX of the clock to the gates.

That is, in FIG. 10, the transmission gates 30a and 30b shown in FIG. 8 are replaced with clocked inverters respectively constituted by transistors 50a, 51a, and 52a, and clocked inverters respectively constituted by transistors 50b, 51b and 52b. Additionally, transistors 41a and 42a are connected to the transistor pair 2, and the transfers 41b and 42b are connected to the transistor pair 4.

In FIG. 10, as an example, a clock signal CK is supplied to the gate of the N-type transistor 50a constituting the clocked inverter on the input side, and an inverted signal CKX of the clock signal is supplied to the gate of the P-type transistor 51a. Alternately, an inverted signal CKX of the clock signal can be supplied to the gate of the N-type transistor 42a connected in series to the transistor pair 2, and a clock signal CK can be supplied to the gate of the P-type transistor 41a.

Thus, when the clocked inverter on the input side is operated and write data is supplied to nodes C1 and C3, the transistor pairs connected to the adjacent nodes C2 and C4 are not operated. For example, when data is written as explained by referring to FIG. 9, there is naturally an influence from a transistor of an adjacent node, but it is possible to speed up the operation by cutting off the influence in the fourth embodiment shown in FIG. 10.

The present invention can be available for not only manufacturers of semiconductor storage devices, for example, memory cells, a latches, etc., but also for all industries using devices that include a semiconductor storage device as a component.

What is claimed is:

1. A semiconductor storage device, comprising:
an inverter composed of a paired N-type transistors and a paired P-type transistors, and each of transistors is disposed on a separate well.

2. A semiconductor storage device, comprising:
four pairs of N-type transistors and P-type transistors coupled to each other; and
a gate-to-node connection device for connecting a gate of each P-type transistor and a gate of each N-type transistor to a connection node for connecting the P-type transistor and the N-type transistor in each pair of transistors in such a direction so as to prevent a potential inversion of a node caused by a soft error from propagating to another node.

3. The device according to claim 2, wherein
said four pairs of transistors form a total of four stages of loop structure in the back and forth directions, and paired transistor sets are formed by a pair and another pair where is two stages backward from said a pair.

4. The device according to claim 3, wherein
the gate-to-node connection device connects the connection node to a gate of a P-type transistor in a pair of transistors at a subsequent stage and a gate of an N-type transistor in a pair of transistors at a preceding stage.

5. The device according to claim 3, wherein
the P-type transistor and the N-type transistor in the paired transistor sets are each disposed on a separate well.

6. The device according to claim 3, wherein
a transistor is connected for reception of an input signal or output of an output signal to the connection nodes of the P-type transistor and the N-type transistor in said each of the four pairs of transistors.

7. The device according to claim 3, wherein
input data is supplied to two connection nodes of the connection nodes in a pair of transistors in a set of paired transistors, and output data is outputted from one of the connection nodes in a pair of transistors in another set of paired transistors.

8. The device according to claim 7, wherein:
a transmission gate for reception of the input data is provided for each of the two connection nodes which receives the input data; and
an inverter is provided between a connection gate for output of the output data and an external unit.

9. The device according to claim 7, wherein
a transmission gate for reception of the input data is connected to the two connection nodes to which receives the input data;
an inverter is connected to the connection node for output of the output data; and
a transistor whose gate receives a clock signal and a transistor whose gate receives an inverted clock signal, connected to each of the transistors in another set of the paired transistors.

10. The device according to claim 9, wherein
a value of clock signal operated by the clocked inverter which receives the input data is the inverse of a value of clock signal according to which the two transistors connected to the another set of the paired transistors are turned on.
